(19) United States
(12) Patent Application Publication
(10) Pub. No.: US 2026/0363077 A1
(43) Pub. Date: Nov. 12, 2026

(54) Power Module, Computer Program Product and Supporting Device with Pulsating Heat Pipe

(71) Applicant: Siemens Aktiengesellschaft, Muenchen (DE)

(72) Inventors: Florian Schwarz, Gerhardshofen (DE); Stephen NEUGEBAUER, Erlangen (DE); Volker MÜLLER, Nürnberg (DE); Stefan STEGMEIER, München (DE); Vladmir DANOV, Erlangen (DE)

(21) Appl. No.: 19/134,256

(22) PCT Filed: Oct. 24, 2023
(86) PCT No.: PCT/EP2023/079567

§ 371 Date: May 30, 2025

(30) Foreign Application Priority Data
Dec. 1, 2022 (EP) 22210750.0

(51) Int. Cl. H10W 40/73

(52) U.S. Cl. CPC H10W 40/73

(57) ABSTRACT

A power module equipped with at least one supporting device, a computer program product that simulates the operational behavior of the supporting device, and a supporting device for mechanically supporting an electrically conductive connection element, from which heat is to be dissipated, on a heat sink, and which electrically insulates the connection element from the heat sink, wherein at least one pulsating heat pipe is formed in the supporting device for dissipating heat from the connection element into the heat sink.

### CROSS-REFERENCE TO RELATED APPLICATIONS

This is a U.S. national stage of application No. PCT/EP2023/079567 filed 24 Oct. 2023. Priority is claimed on European Application No. 22210750.0 filed 1 Dec. 2022, the content of which is incorporated herein by reference in its entirety.

### BACKGROUND OF THE INVENTION

### 1. Field of the Invention

The invention relates to a computer program product for simulating an operational behavior of a supporting apparatus, a supporting apparatus for an electrically conductive connecting element and a power module which comprises such a supporting apparatus.

### 2. Description of the Related Art

PCT/EP2022/075791 (WO/2023/052151) discloses a thermally conductive holder, in which channels are formed that can be used as heat pipes. The channels extend essentially along a cylinder outer surface in a plastic body and are closed on end faces of the holder by metal elements.

European patent application EP 3 336 471 A1 discloses an electronic substrate that is to be cooled. The electronic substrate has channels that pass through it and that lie in a substrate plane. The channels form a loop and are used as a pulsating heat pipe.

U.S. Pat. No. 6,672,373 B2 describes a pulsating heat pipe that has different diameters and curvature radii in sections.

The pulsating heat pipe is also provided with compensating vessels for its fluid.

Electrical power circuits with increasing electrical power are used in a wide range of applications. Accordingly, increased demands are placed on the heat dissipation of such circuits. At the same time, the objective is to achieve cost-efficient and reliable heat dissipation in electrical power circuits. Low-wear operation is also a priority. This particularly applies to the heat dissipation of electrically conductive connecting elements of such electrical power circuits, such as their conductor rails.

### SUMMARY OF THE INVENTION

It is an object of the invention to provide the possibility for dissipating heat of an electrical power circuit which offers an improvement in at least one of the aspects outlined above.

This and other objects and advantages are achieved in accordance with the invention by a supporting apparatus that is suitable for mechanically supporting an electrical conductive connecting element that is to be cooled. The mechanical support can be point-based. The electrically conductive connecting element can, for example, be formed as a conductor rail. The electrically conductive connecting element, also referred to below only as a connecting element, belongs to an electrical power circuit, by way of example a power module, and is mechanically supported by the supporting apparatus on a heat sink into which heat from the connecting element is to be dissipated. The connecting element is electrically insulated from the heat sink by the supporting apparatus. For this purpose, the supporting apparatus can be produced, for example, at least in part from a plastic. In accordance with the invention, at least one pulsating heat pipe is formed in the supporting apparatus and heat can be transported through the heat pipe from the connecting element to the heat sink. Such pulsating heat pipes are also referred to by the technical term pulsating heat pipes. In the present application, the pulsating heat pipes are also referred to in short as heat pipes. The at least one pulsating heat pipe can be formed as a closed circuit or as a pulsating heat pipe with two ends. Here, the pulsating heat pipe can form a loop. The at least one pulsating heat pipe is structured for transporting heat from the connecting-element side end to the heat sink-side end of the supporting apparatus. As a result, the pulsating heat pipe is consequently used in the supporting apparatus to dissipate heat from the connecting element to the heat sink. In so doing, the heat sink can be formed as a cooling body, as housing components or as a component of another electrical power circuit.

The pulsating heat pipe provides powerful heat dissipation that can be self-operating, i.e., uncontrolled, and can be miniaturized. The pulsating heat pipe is also geometrically adaptable and can therefore be integrated into a wide variety of different types of supporting apparatuses. Moreover, the supporting apparatus can be produced at least in part from electrically insulating plastic which has reduced thermal conductivity. The use of cost-intensive materials that are electrically insulating and at the same time have increased thermal conductivity is minimized in the supporting apparatus in accordance with the invention. The supporting apparatus can be produced at least in part from a plastic that is simple to process, which in turn renders it possible to produce the at least one pulsating heat pipe rapidly, simply and at the same time precisely.

In the supporting apparatus in accordance with the invention, the at least one pulsating heat pipe is provided at least in part with a diffusion-inhibiting coating. The diffusion-inhibiting coating can be formed as a metal coating or ceramic or glass-like coating. The diffusion-inhibiting coating is configured so as to prevent fluids, such as water vapor, or gases from the ambient air from flowing into the pulsating heat pipe. As a result, it is possible to prevent or reduce fluid contamination in the pulsating heat pipe. At least one pulsating heat pipe can have a negative pressure relative to the ambient air, which can be altered by contamination. Such pulsating heat pipes can be operated reliably over the long term with a corresponding coating. This ensures an overall increase in the service life of the inventive supporting apparatus.

In one embodiment of the inventive supporting apparatus, the supporting apparatus is produced in a middle section from a first material that has a first thermal conductivity. Moreover, the supporting apparatus is produced at one connecting element-side end and/or a heat sink-side end from a second material which has a second thermal conductivity. The middle section is understood here as a section of the supporting apparatus between the connecting element-side end and the heat sink-side end. In the middle section, thermal edge effects that occur at the connecting element-side end and/or at the heat sink-side end can be minimized. Furthermore, the second thermal conductivity can be higher than the first thermal conductivity. This achieves improved thermal coupling of the supporting apparatus to the connecting element and/or the heat sink. The first and second material can each be a plastic in which a predeterminable concentration of heat-conducting particles and/or fibers is present. The heat-conducting particles can be added to the plastic by an additive manufacturing process, for example. The particles or fibers can be produced at least in part from glass, ceramic, a metal material, or carbon. Furthermore, the particles and/or fibers can be incorporated into the corresponding component of the supporting apparatus such that they are in electrical contact with at most the heat sink-side end or the connecting element-side end. The middle section and the connecting element-side or heat sink-side end made of the first or second material can be formed as separate components of the supporting apparatus or be can formed as one piece. Furthermore, the middle section, the connecting element-side end and/or the heat sink-side end can be manufactured by injection molding. A largely discrete boundary can be provided between the first and second material, or a predeterminable transition. Both the discrete boundary and the predeterminable transition can be produced, for example, by an additive manufacturing process. Alternatively or in addition, an adhesive bond or a welded joint can also be provided at the predeterminable transition. Furthermore, a sealing element can also be arranged at the predeterminable transition. If the middle section and the connecting element-side end or the heat sink-side end are formed as separate components, i.e., the supporting apparatus is of a differential configuration, then these can be produced entirely from the first or second material.

Furthermore, a mounting base can be formed on the connecting element-side end and/or on the heat sink-side end of the claimed supporting apparatus. The mounting base can be formed on the connecting element-side end or the heat sink-side end and can be of an essentially two-dimensional structure. The at least one pulsating heat pipe extends at least in part through the mounting base. The mounting base provides an enlarged area on the connecting element and/or on the heat sink for heat coupling the supporting element.

In a further embodiment of the inventive supporting apparatus, at least one pulsating heat pipe is filled at least partially with an electrically conductive fluid. The electrically conductive fluid can be water or an aqueous solution, for example. The inventive supporting apparatus electrically insulates the connecting element from the heat sink so that there is no risk of the heat sink being electrically charged when an electrically conductive fluid is used. It is not necessary in the inventive supporting apparatus to use electrically insulating fluids or fluids with negligible electrical conductivity <100 μS/cm, in particular <10 μS/cm. Accordingly, a broader range of fluids is available, via which the heat transport properties of the pulsating heat pipe can be specified more precisely. In particular, water, ethanol, coolant, a ferrofluid, an electrofluid, or a dielectric fluid, such as perfluoro (2-methyl-3-pantatone), can be used as the fluid. The fluid can be mixed with metal particles, via which a prevailing heat dissipation capacity of the at least one pulsating heat pipe can be measured. The inventive supporting apparatus can be produced in an overall cost-efficient manner and can be adapted to a wide range of applications in accordance with requirements.

Furthermore, the inventive supporting apparatus can be formed as one piece. The supporting apparatus can be produced essentially entirely by additive manufacturing, such as 3D printing. Additive manufacturing renders it possible to produce a larger number of pulsating heat pipes with the same installation space and reduced clear diameters and/or reduced curvature radii of the at least one pulsating heat pipe. This makes the at least one pulsating heat pipe suitable for dissipating heat even in delicate sections of the supporting apparatus. As a result, increased heat dissipation can be achieved. Alternatively, the inventive supporting apparatus can comprise a core section and a bell section. The bell section can be placed over the core section during assembly. The at least one pulsating heat pipe can be formed from a recess or a combination of recesses on the core section and/or on the bell section. The recess or combination of recesses can be each produced by injection molding or solid forming or by machining the core section and/or the bell section. The core section and the bell section can be produced quickly and simply, which in turn makes the inventive supporting apparatus cost-efficient to produce. The bell section can also be used to form the connecting element-side end or the heat sink-side end of the supporting apparatus. If contact surfaces at the connecting element-side end and at the heat sink-side end are not parallel, then the bell section can comprise both the heat sink-side end and the connecting element-side end of the supporting apparatus. In particular, the core section can be produced from the first material with the first thermal conductivity and the bell section can be produced from the second material with the second thermal conductivity. Alternatively, the core section and/or the bell section can also be produced in sections from the first or second material. The heat transport behavior of the at least one pulsating heat pipe can therefore be further adjusted by the construction of the core section and the bell section. In addition, the bell section and the core section can also be conical in shape, in particular have a draft angle, which improves mutual fit. In particular, gaps between multiple adjacent pulsating heat pipes can be easily avoided in this manner. The bell section and/or the core section can have different optical transmission properties, which means that they can be joined together via laser beam welding, for example. The bell section can also be produced from a transparent material, which allows easy visual inspection of the supporting apparatus.

Moreover, in the inventive supporting apparatus, a plurality of pulsating heat pipes can be formed in the area of a circumferential wall, which lies between the connecting element-side end and the heat sink-side end. The circumferential wall can extend from the connecting element-side end to the heat sink-side end and connect them. The circumferential wall defines a surface area of the supporting apparatus in the middle section. The circumferential wall can be formed essentially as a cylinder outer surface. Alternatively, the circumferential wall can be formed as any circumferential outer surface. The pulsating heat pipes can be located within the supporting apparatus in the region of its surface area, which facilitates heat dissipation to the ambient air. The pulsating heat pipes can extend up to 5 mm below a surface area of the circumferential wall in the middle section of the supporting apparatus. Accordingly, an enlarged surface area is available for pulsating heat pipes, which further supports the heat dissipation of the connecting element. The availability of an enlarged surface area allows the recesses for the pulsating heat pipes to be produced with increased manufacturing tolerance, which in turn simplifies production. Moreover, in the case of a supporting apparatus which has a bell section and a core section, the bell section has a thin wall which also facilitates a simplified production, such as by injection molding.

In a further embodiment of the inventive supporting apparatus, the diffusion-inhibiting coating can be produced by gas phase deposition, physical vapor deposition, a sol-gel process, thermal spraying, vapor deposition, autocatalytic coating, or by an electroplating process.

Furthermore, in the inventive supporting apparatus, its circumferential wall, its connecting element-side end and/or its heat sink-side end can be provided with a diffusion-inhibiting coating. The diffusion-inhibiting coating can be formed as a metal coating, ceramic or glass-like coating. At least one pulsating heat pipe can have negative pressure relative to the ambient air. The diffusion-inhibiting coating can reduce or prevent the penetration of fluids, such as water vapor, or gases from the ambient air into the supporting apparatus. The coating of the circumferential wall, the connecting element-side end, and/or the heat sink-side end can be formed on their surface or arranged inside them. A coating on the surface can be produced in a particularly simple manner. A coating that lies inside the circumferential wall, the connecting element-side end and/or the heat sink-side end is in turn itself protected by the respective component. As a result, the coating can be made from a material that is chemically unstable when in prolonged contact with the ambient air. By avoiding mechanical stresses, it is possible for the coating to have a reduced coating thickness. Such coatings can also be produced via additive manufacturing. Moreover, such a coating provides the inventive supporting apparatus with increased insulation strength.

In the inventive supporting apparatus, the at least one pulsating heat pipe can also be closed by the heat sink and/or the connecting element that is to be cooled. The at least one pulsating heat pipe can be structured as a through-going bore that extends in the area of the circumferential wall through the middle section of the supporting apparatus. The at least one pulsating heat pipe can be continued as a recess on end faces of the supporting apparatus, i.e., essentially as an open channel that is closed by the connecting element or the heat sink in the assembled state. In such a supporting apparatus, an electrically insulating fluid is used in the pulsating heat pipe. A corresponding supporting apparatus has a reduced number of components and is therefore particularly simple to manufacture. Moreover, a more direct heat-conducting contact to the connecting element or heat sink can be established in this manner.

Moreover, the inventive supporting apparatus can comprise a sensor that is configured to detect at least one physical variable of the pulsating heat pipe and/or a component of the supporting apparatus. For example, the sensor can be configured as a pressure sensor or temperature sensor, via which the pressure or temperature of the fluid in the pulsating heat pipe can be detected. The pressure or temperature of the fluid allows conclusions to be drawn about the extent to which the heat transport capacity of the pulsating heat pipe is being utilized at a given measurement time. The sensor can also be configured to detect vibrations. Moreover, the sensor can be configured to perform so-called energy harvesting. For this purpose, the sensor can, for example, have a thermoelectric generator or a piezo membrane and/or obtain electrical energy by induction for its operation. This allows the sensor to be operated reliably over a long period of time. Furthermore, the sensor can have a communication unit, in particular a wireless communication unit. This makes it easy to monitor the condition of the supporting apparatus. Based on data obtained via the sensor, an application in which the supporting apparatus is used, such as a power module, can be optimized in terms of thermal stress. Similarly, faults can be detected and the remaining technically usable service life of the supporting apparatus can be estimated.

Furthermore, the inventive supporting apparatus can have a recess at the connecting element-side end and/or the heat sink-side end, via which an indented surface is formed. The recess can be formed on an end face of the supporting apparatus, for example. The indented surface serves to couple heat to the connecting element or heat sink to be cooled. The recess forms an enlarged surface area in the area of the connecting element-side end or heat sink-side end, at which a thermally conductive contact can be established with the connecting element or heat sink. This allows improved heat coupling to be achieved while saving space. The inventive supporting apparatus can therefore be adapted to such applications with increased miniaturization, in particular power modules. The at least one heat pipe can extend in the region of the recess, in particular a wall that bounds the recess. The pulsating heat pipe can be formed in a substantially U-shape in the area of the recess. The recess also provides centering for mounting the supporting apparatus. In particular, the recess can be formed in an end face of a core section of the supporting apparatus. The recess in the core section centers the associated bell section of the supporting apparatus. Moreover, a coupling element produced from a metal material can be accommodated in the recess which forms the indented surface for heat coupling. The coupling element is configured to form a thermal connection between the connecting element or heat sink and the supporting apparatus via the indented surface. Moreover, the indented surface and/or the coupling element can be conically shaped, which ensures a simple and precise production. In addition, the indented surface and/or the coupling element can be configured to press against each other or can be undercut, which allows a form-fitting connection to be created. Moreover, the indented surface and the coupling element can be connected to each other via an adhesive bond. The coupling element can be formed as a bushing and/or can be configured to form a detachable connection with the connecting element or the heat sink. For this purpose, the coupling element can be provided with a threaded bore, for example. In the assembled state, the coupling element is exposed to minimized tensile and peel stresses. Instead, the coupling element is predominantly subjected to shear stresses. This means that the coupling element is subjected to mechanical stresses that are appropriate for the component.

In a further embodiment, the inventive supporting apparatus is at least partly produced by an additive manufacturing process. The supporting apparatus can be formed for this purpose as one piece and can be produced in sections by an additive manufacturing process or as components. Additive manufacturing processes allow the supporting apparatus to be produced with locally adjustable properties, in particular thermal conductivity properties, via a predeterminable mixture of additives, such as heat-conducting particles. Moreover, additive manufacturing processes allow filigree or geometrically complex, for example, interlocking pulsating heat pipes to be produced simply and cost-effectively. This allows the technical properties of the materials used to be exploited to a greater extent. This, in turn, allows for greater miniaturization of the inventive supporting apparatus. The additive manufacturing process can be, for example, 3D printing, powder-bed-free printing, in particular fused deposition modeling, stereolithography, or a jetting process.

The objects and advantages are also achieved in accordance with the invention by a performance module. The performance module can belong to a so-called power module or a converter, for example. The power module comprises a substrate that is provided with at least one electrically conductive connecting element, for example, a conductor rail that is to be cooled when the power module is in an active operating state. The connecting element is supported in the power module by a supporting apparatus on a heat sink into which the connecting element is to be cooled. In accordance with the invention, the supporting apparatus is formed in accordance with at least one of the disclosed embodiments. The features of the inventive supporting apparatus can consequently be transferred in a similar manner to the power module in accordance with the invention. Together with a higher-level control unit, the inventive power module can belong to a system via which the above described object is also achieved. The system is configured to monitor the operating status of the power module. For this purpose, at least one supporting apparatus in the power module has a sensor that is directly or indirectly coupled to the higher-level control unit for communication. The higher-level control unit is configured to evaluate data received from the sensor and issue a warning. The higher-level control unit can be integrated into the power module.

Moreover, the object and advantages are achieved in accordance with the invention by a computer program product, which is configured to simulate an operational behavior of a supporting apparatus. The operational behavior to be simulated can be present during an active operation of a power module in which the supporting apparatus is arranged. The computer program product comprises commands which, when executed by a processor of computer, cause the computer to simulate the operating behavior. In accordance with the invention, the supporting apparatus is configured in accordance with one of the disclosed embodiments. The features outlined above can also be transferred in a similar manner to the computer program product in accordance with the invention.

The computer program product can have a physics module for simulation in which the supporting apparatus is at least in part represented. For this purpose, the supporting apparatus can, for example, be replicated in its structure and mode of operation, for example, as a digital image belonging to the computer program product. Alternatively or in addition, the supporting apparatus can also be configured as a calculation model in the physics module. The physics module is configured, among other things, to simulate the thermal behavior of the supporting apparatus, the flow behavior, the evaporation behavior, and/or the condensation behavior of the fluid used therein under adjustable operating conditions. The adjustable operating conditions include, for example, an ambient temperature, a pressure of the fluid, its temperature, a thermal conductivity of the fluid and/or of the individual components of the supporting apparatus, a temperature of the connecting element to be cooled, and/or a temperature of the heat sink. The computer program product can have a data interface via which appropriate data can be specified via user input, a data connection to a higher-level control unit of a real system with a power module with a corresponding supporting apparatus and/or other simulation-oriented computer programs. The computer program product can also have a data interface for outputting simulation results to a user and/or other simulation-oriented computer program products. The computer program product can be used, for example, to detect a defective supporting apparatus, a faulty connection between the supporting apparatus and the heat sink or the connecting element, and/or a leak in at least one pulsating heat pipe. In particular, the operational behavior of the real supporting apparatus, expressed for example by measured values from a sensor installed therein or sensors in the power module, can be checked for plausibility by comparison with the simulated supporting apparatus. For example, the operational behavior of a pulsating heat pipe can be simulated realistically. The at least one pulsating heat pipe can be reproduced as a two-dimensional model in the claimed computer program product. Pulsating heat pipes can be simulated with high realism and minimized computing effort. The supporting apparatus can therefore be easily modeled, i.e., its operational behavior can be recalculated with a minimum of Computational Fluid Dynamics (CFD) calculations. In particular, the heat transport behavior in the pulsating heat pipe can be approximated with sufficient precision by algebraic calculation. The computer program product in accordance with the invention thus allows modeling of the underlying supporting apparatus with reduced computing power requirements. This also allows a large number of such supporting apparatuses to be replicated, such as in a power module. Overall, a particularly realistic process image of the operation of a corresponding application can thus be provided in a simple manner. Similarly, the inventive computer program product can easily achieve real-time capability as a result of the reduced computing effort, which in turn allows powerful monitoring of a corresponding supporting apparatus or corresponding power module. The computer program product can be formed as a “digital twin”, as described, for example, in US 2017/286572 A1, the content of which is incorporated herein by reference in its entirety. Accordingly, the digital twin is configured to correspond to the supporting apparatus in accordance with the disclosed embodiments. The computer program product can be implemented in a monolithic manner, i.e., completely on a hardware platform. Alternatively, the computer program product can be configured in a modular manner and can comprise a plurality of sub-programs that can be executed on separate hardware platforms and can cooperate via a communicative data connection. Such a communicative data connection can be a network connection, an internet connection and/or a mobile radio connection. Moreover, the computer program product in accordance with the invention renders it possible to trial and/or optimize a supporting apparatus by simulation.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention is explained in detail below with the aid of individual embodiments in figures. The figures are to be read as complementary to each other in that the same reference characters in different figures have the same technical meaning. The features of the individual embodiments can also be combined with each other. Moreover, the embodiments that are illustrated in the figures can be combined with the features outlined above, in which:

FIG. 1 shows an oblique view of a power module with an embodiment of the inventive supporting apparatus;

FIG. 2 shows a longitudinal sectional view of a first embodiment of the inventive supporting apparatus;

FIG. 3 shows an oblique view of a second embodiment of the inventive supporting apparatus;

FIG. 4 shows an oblique view of a third embodiment of the inventive supporting apparatus;

FIG. 5 shows an oblique view of the third embodiment of the inventive supporting apparatus in an assembled state; and

FIG. 6 shows an oblique view of the third embodiment of the inventive supporting apparatus in the assembled state.

### DETAILED DESCRIPTION OF THE EXEMPLARY EMBODIMENTS

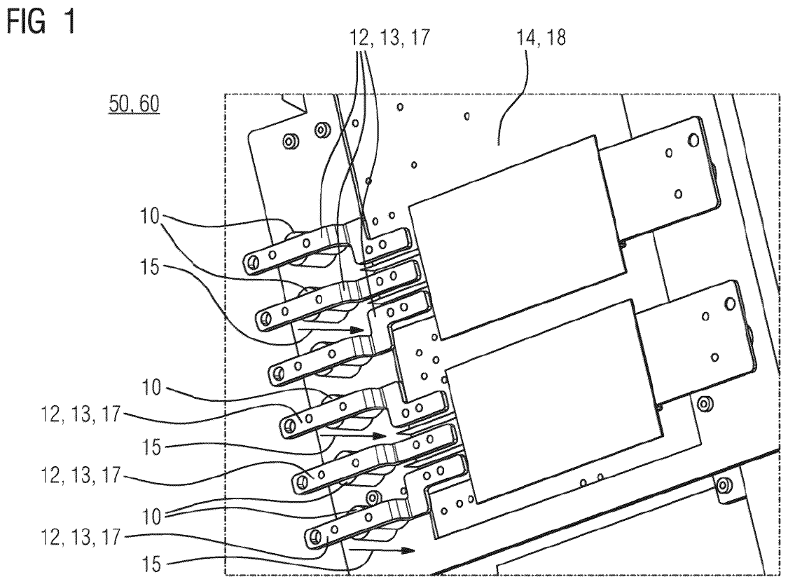

FIG. 1 shows an oblique view of an embodiment of a power module 50 in which at least one supporting apparatus 10 in accordance with the invention is used. The power module 50 comprises a plurality of electrically conductive connecting elements 12, which are each formed as a conductor rail 17. The electrically conductive connecting elements 12 are also referred to below only as connecting elements 12. The connecting elements 12 are heated when the power module 50 is in an active operating state and must therefore be cooled. The connecting elements 12 are each mechanically supported by a supporting apparatus 10 on a housing component 18, which serves as a heat sink 14. Alternatively or in addition, a cooling body that is not shown can also be used as a heat sink 14. The connecting elements 12 are correspondingly each to be understood as a heat source 13. During normal operation of the power module 50, a heat flow 15 is present from each of the connecting elements 12, i.e., a heat source 13, to the heat sink 14. The heat flows 15 each pass through the corresponding supporting apparatuses 10. At least one of the supporting apparatuses 10 is configured in accordance wit the disclosed embodiments. The operating behavior of the at least one supporting apparatus 10, which is configured in accordance with the disclosed embodiments, is simulated by a computer program product 60, which is not shown in detail. The computer program product 60 can be configured as a “digital twin” of the corresponding supporting apparatus.

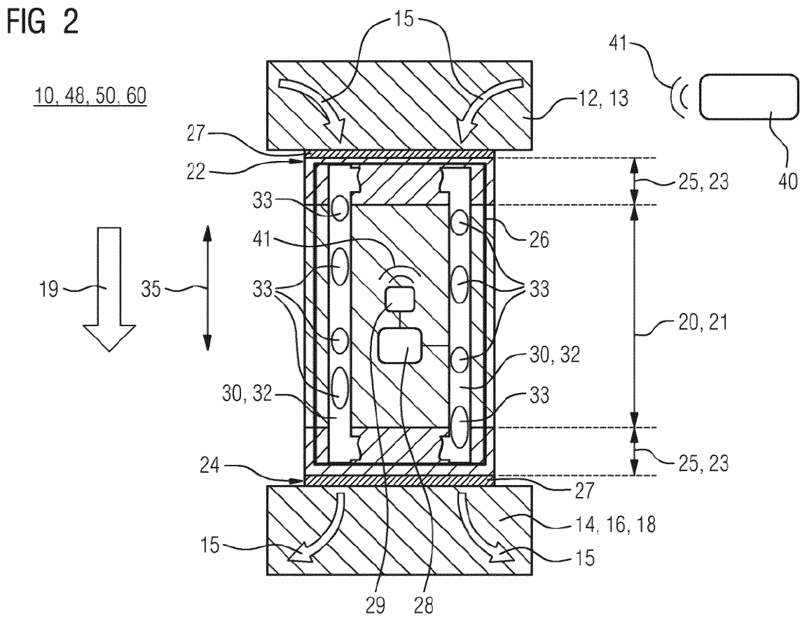

FIG. 2 shows a schematic longitudinal sectional view of a first embodiment of the inventive supporting apparatus 10. The supporting apparatus 10 is arranged between an electrically conductive connecting element 12, which forms a heat source 13, and a heat sink 14, which can be formed as a housing component 18 or as a heat sink 16. The supporting apparatus 10 is formed as one piece and comprises a middle section 20 located between an end section 25 at a connecting element-side end 22 and a heat sink-side end 24, respectively. In the middle section 20, the supporting apparatus 10 is produced from a first material 21 that has a first thermal conductivity. In the region of the connecting element-side end 22 and at the corresponding end section 25, the supporting apparatus 10 is produced from a second material 23 that has a second thermal conductivity. Similarly, the supporting apparatus 10 is produced from the second material with the second thermal conductivity in the area of its heat sink end 24, i.e., in the corresponding end section 25. The second thermal conductivity is higher than the first thermal conductivity. The first and second material are each a plastic that is suitable for additive manufacturing and to which thermally conductive particles are added in an adjustable form, i.e., in essentially selectable concentrations. The different thermal conductivities in the first and second material 21, 23 are set by presetting a concentration of thermally conductive particles during additive manufacturing of the supporting apparatus. A heat flow 15 from the heat source 13 flows through a heat-conducting paste layer 27 at the connecting element-side end 22 and enters the supporting apparatus 10 in the end section 25 at the connecting element-side end 22.

The heat flow 15 entering at the connecting element-side end 22 causes partial evaporation of a fluid 32 that is accommodated in a plurality of pulsating heat pipes 30. The pulsating heat pipes 30 are each formed as recesses within the supporting apparatus 10 and are arranged inside the supporting apparatus 10. Accordingly, the pulsating heat pipes 30 are closed by the supporting apparatus 10 itself. The fact that the second thermal conductivity in the end section 25 at the connecting element-side end 22 is higher than the first thermal conductivity in the middle section 20 supports the evaporation of the fluid 32. Vapor phases 33 form in the pulsating heat pipes 30 and move as bubbles along the pulsating heat pipe 30. During normal operation, the vapor phases 33 oscillate 35 so that it is ensured that heat is transported to the heat sink end 24. Overall, this results in heat dissipation 19 from the connecting element 12 into the heat sink 14. Correspondingly to the incoming heat flow 15 at the connecting element-side end 22, the heat flow 15 exits the pulsating heat pipes 30 at the heat sink end 24. The end section 25 at the heat sink-side end 24 is made of the second material 23, which supports heat transfer from the pulsating heat pipes 30 into the corresponding end section 25. The heat flow 15 entering the heat sink 14 from the supporting apparatus 10 flows through a heat-conducting paste layer 27 arranged between the supporting apparatus 10 and the heat sink 14.

The fluid 32 has a negative pressure relative to the ambient air 48 in which the supporting apparatus 10 is used. A diffusion-inhibiting coating 26 is formed in the supporting apparatus 10 and minimizes the penetration of gases or liquids from the ambient air 48 into the pulsating heat pipes 30. The diffusion-inhibiting coating can be formed as a metal or ceramic coating. The diffusion-inhibiting coating 26 can also be produced by additive manufacturing. The pulsating heat pipes 30 ensure efficient and self-regulating heat dissipation 19 of the connecting element 12 to the heat sink 14.

Furthermore, arranged in the supporting apparatus 10 is a sensor 28, which is coupled to one of the pulsating heat pipes 30. The sensor 28 is configured to detect a physical variable of the pulsating heat pipe 30, for example, a temperature or a pressure of the fluid 32 in the corresponding pulsating heat pipe 30. The sensor 28 is connected to a communication unit 29. The communication unit 29 is in turn connected to a higher-level control unit 40 via a communicative data connection 41, such as a wireless connection. The higher-level control unit 40 is configured to monitor the heat dissipation 19 and can belong to the power module 50 in which the supporting apparatus 10 is used. There is also a computer program product 60, which is not shown in detail, which is configured as a “digital twin” of the supporting apparatus 10. The computer program product 60 can comprise an image, in particular a digital image, of the supporting apparatus 10 and can be configured to simulate a prevailing operational state of the supporting apparatus 10. The computer program product 60 allows physical variables detected by the sensor 28 to be checked, in particular for plausibility. The computer program product 60 can, for example, be stored in an executable form on the higher-level control unit 40 that includes memory (not shown).

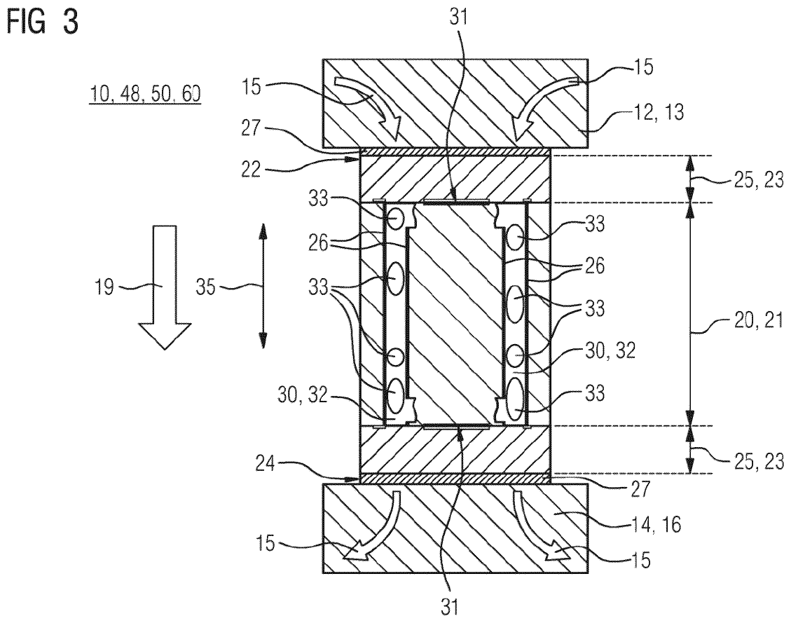

A second embodiment of the inventive supporting apparatus 10 is shown schematically in a longitudinal section in FIG. 3. The supporting apparatus 10 is arranged between an electrically conductive connecting element 12, which forms a heat source 13, and a heat sink 14, which can be formed as a housing component 18 or as a cooling body 16. The supporting apparatus 10 is produced from a plurality of components that are connected to one another. These are connected to one another via material-locking connections 31. The supporting apparatus 10 comprises a middle section 20 that lies between an end section 25 at a connecting element-side end 22 and a heat sink-side end 24. In the middle section 20, the supporting apparatus 10 is produced from a first material 21 that has a first thermal conductivity. The end section 25 on the connecting element-side end 22 is produced from a second material 23 which has a second thermal conductivity. Similarly, the supporting apparatus 10 is produced from the second material with the second thermal conductivity in the area of its heat sink end 24, i.e., in the corresponding end section 25. The second thermal conductivity is higher than the first thermal conductivity. The first and second material are each a plastic that is suitable for additive manufacturing and to which thermally conductive particles are added in an adjustable form, i.e., in essentially selectable concentrations. The different thermal conductivities in the first and second material 21, 23 are each set by presetting a concentration of thermally conductive particles during additive manufacturing of the supporting apparatus. A heat flow 15 from the heat source 13 flows through a heat-conducting paste layer 27 at the connecting element-side end 22 and enters into the end section 25 at the connecting element-side end 22 into the supporting apparatus 10.

The heat flow 15 entering at the connecting element-side end 22 causes partial evaporation of a fluid 32 that is accommodated in a plurality of pulsating heat pipes 30. The pulsating heat pipes 30 are each formed as recesses within the supporting apparatus 10 and are arranged inside the supporting apparatus 10. Accordingly, the pulsating heat pipes 30 are closed by the end sections 25 of the supporting apparatus 10. The fact that the second thermal conductivity in the end section 25 at the connecting element-side end 22 is higher than the first thermal conductivity in the middle section 20 supports the evaporation of the fluid 32. Vapor phases 33 form in the pulsating heat pipes 30 and move as bubbles along the pulsating heat pipe 30. During normal operation, the vapor phases 33 oscillate 35 so that heat is transported to the heat sink end 24. Overall, this results in heat dissipation 19 from the connecting element 12 to the heat sink 14. Correspondingly to the incoming heat flow 15 at the connecting element-side end 22, the heat flow 15 exits the pulsating heat pipes 30 at the heat sink end 24. The end section 25 at the heat sink-side end 24 is made of the second material 23, which supports heat transfer from the pulsating heat pipes 30 into the corresponding end section 25. The heat flow 15 entering the heat sink 14 from the supporting apparatus 10 flows through a heat-conducting paste layer 27 arranged between the supporting apparatus 10 and the heat sink 14.

The fluid 32 has a negative pressure relative to the ambient air 48 in which the supporting apparatus 10 is used. A diffusion-inhibiting coating 26 is formed in the supporting apparatus 10 and minimizes the penetration of gases or liquids from the ambient air 48 into the pulsating heat pipes 30. The diffusion-inhibiting coating can be formed as a metal or ceramic coating. The diffusion-inhibiting coating 26 can also be produced by additive manufacturing. The pulsating heat pipes 30 ensure efficient and self-regulating heat dissipation 19 of the connecting element 12 into the heat sink 14. The diffusion-inhibiting coating 26 is applied in the recesses, i.e., on inner surfaces of the pulsating heat pipes 30. As a result, the middle section 20 can be used as a protective absorption section that absorbs fluids, such as gases, from the ambient air 48 and thus minimizes or prevents them from penetrating the pulsating heat pipes 30. Diffusion-inhibiting coatings 26 are also applied in the section of a boundary between the middle section 20 and the end sections 35. These are configured so as to minimize the penetration of fluid from the ambient air 48 via the end sections 25 on the connecting element-side end 22 or the heat sink-side end 24. There is also a computer program product 60, which is not shown in detail, which is configured as a “digital twin” of the supporting apparatus 10. The computer program product 60 can comprise an image, in particular a digital image, of the supporting apparatus 10 and be configured to simulate a prevailing operating state of the supporting apparatus 10.

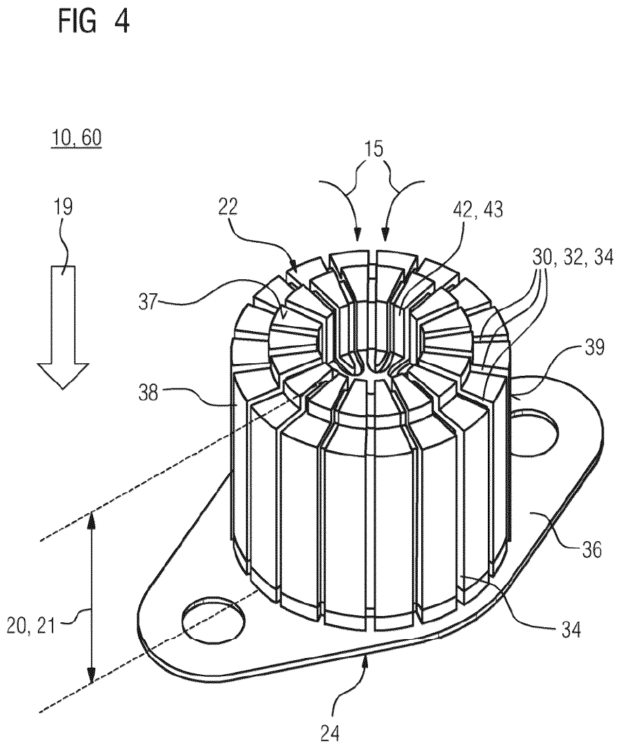

A third embodiment of the inventive supporting apparatus 10 is shown in FIG. 4 in an unassembled state in an oblique view. The supporting apparatus 10 comprises a core section 38 that is formed in an essentially cylindrical manner and on its circumferential wall 39 which is formed as a cylinder outer surface on which in turn a plurality of recesses 34 is provided. In an assembled state, the recesses 34 form the pulsating heat pipes 30 that accommodate a fluid 32 that provides the desired heat dissipation 19. The recesses 34 extend in a middle section 20 from a heat sink-side end 22a to connecting element-side end 24. In the unassembled state, the recesses 34 form essentially open channels. The core section 38 is produced from a first material 21 that is in the form of a plastic. At the connecting element-side end 22, the core section 38 has an end surface 37 on which the recesses 34 continue. The recesses 34 are formed on the end surface 37 in an essentially star-shaped manner. An essentially middle recess is formed on the end surface 37 and creates an indented surface 42. The recesses 34 which, in the assembled state, form the pulsating heat pipes 30 also extend along the indented surface 42. The indented surface 42 is circumferential and in the assembled state is used to heat couple 43 the core section 38, i.e., in the area of the connecting element-side end 22 of the supporting apparatus 10. The indented surface 42 creates an enlarged surface area for a heat flow 15 that is to be transported from a connecting element 12, which is not shown in detail, to a heat sink 14, which is not shown in detail, i.e., to the cooling body 16 or the housing component 18 via the pulsating heat pipes 30. The core section 38 can also be formed as a hollow body, which simplifies production via injection molding.

The supporting apparatus 10 is provided on the heat sink-side end 24 with a mounting base 36, via which the supporting apparatus 10 can be coupled to the heat sink 14. The coupling to the heat sink 14 includes a mechanical coupling and a thermal coupling. There is also a computer program product 60, which is not shown in detail, which is configured as a “digital twin” of the supporting apparatus 10. The computer program product 60 can comprise an image, in particular a digital image, of the supporting apparatus 10 and can be configured to simulate a prevailing operating state of the supporting apparatus 10.

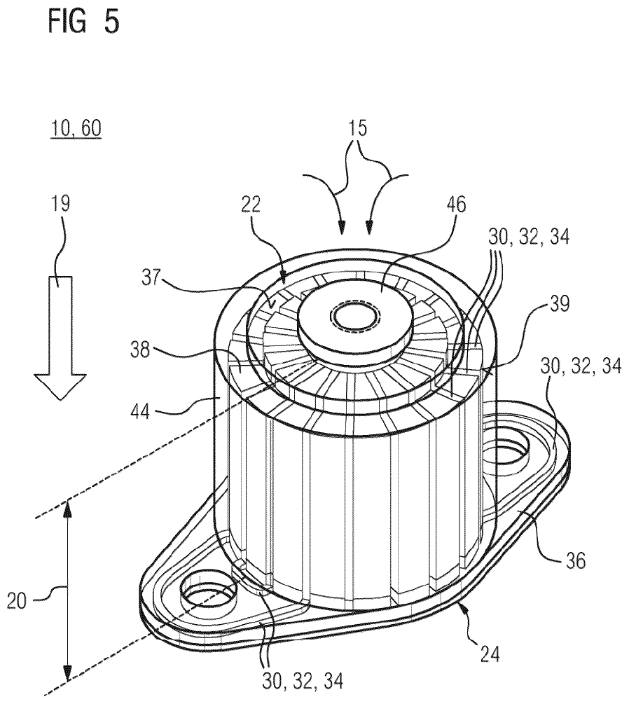

The third embodiment of the claimed supporting apparatus 10, as shown in FIG. 4, is shown in FIG. 5 in an assembled state in an oblique view. The descriptions relating to FIG. 4 also apply analogously to FIG. 5. In FIG. 5, the core section 38 is connected to a bell section 44, which is essentially placed over the core section 38. For clarity, the bell section 44 is shown transparent in FIG. 5. The bell section 44 is essentially formed as a hollow cylinder closed on one side and open on one side. The recesses 34 on the core section 38, which form channels in the unassembled state, are closed by the bell section 44 at least in the middle section 20 and are thus suitable for accommodating the fluid 32 via which the functionality of the pulsating heat pipes 30 is achieved. A mounting base 36 is also formed on the bell section 44 and its shape corresponds to the mounting base 36 of the core section 38. Alternatively, the mounting base 36 can also be formed as a separate component that is connected to the core section 38 during the production of the supporting apparatus 10. Recesses 34 are formed in the mounting base 36 of the bell section 44, which extend through the mounting base 36. The recesses 34 in the mounting base 36 of the bell section 44 are connected to recesses 34 on the core section 38, so that these are also partially filled with fluid 32. Accordingly, pulsating heat pipes 30 are also formed by the recesses 34 in the mounting base 36 of the bell section 44. The enlarged surface area of the mounting base 36 on the core section 38 or on the bell section 44 improves the thermal coupling of the supporting apparatus 10 to the heat sink 14, which is not shown in detail. The core section 38 and/or the bell section 44 can be produced by additive manufacturing, so that an increased proportion of their mounting bases 36 can be used for pulsating heat pipes 30 and thus for the desired heat dissipation 19. As a result, the inventive supporting apparatus 10 can be better utilized thermally. The fluid 32 is electrically insulated from the connecting element 12 via the mounting base 36. Accordingly, the fluid 32 itself can be electrically conductive.

The core section 38 is also covered in the area of its end face 37 and thus closes the recesses 34, which form open channels in the unassembled state. At the connecting element-side end 22, a coupling element 46 made of a metal material is arranged on the bell section 44. The coupling element 46 is configured to contact the connecting element 12, which is not shown in detail, and thus to introduce a heat flow 15 into the supporting apparatus 10. The bell section 44 has a recess in the area of the indented surface 42, as shown in FIG. 4 and this recess accommodates the coupling element 46. The coupling element 46 is made of a metal material. Accordingly, the coupling element 46 has increased thermal conductivity compared to the first material 21 on which the middle section 20 of the core section 38 is produced. The enlarged surface area on the indented surface 42 thus allows an increased heat flow 15 to be introduced into the pulsating heat pipes 15. The core section 38 and the bell section 44 can be manufactured in a simple manner, for example, by additive manufacturing or injection molding, and offer increased capacity for heat dissipation 19 of the connecting element 12. Accordingly, the functional integration of mechanical support and heat dissipation is achieved in a particularly cost-efficient manner. There is also a computer program product 60, which is not shown in detail, which is formed as a “digital twin” of the supporting apparatus 10. The computer program product 60 can comprise an image, in particular a digital image, of the supporting apparatus 10 and can be configured to simulate a prevailing operating state of the supporting apparatus 10.

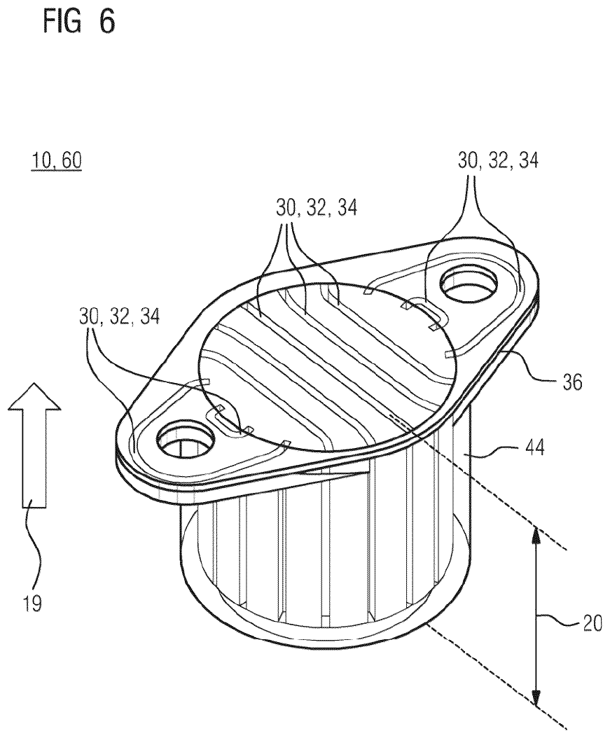

Moreover, the third embodiment of the claimed supporting apparatus 10 is shown in FIG. 6 in the assembled state in an oblique view from below. For clarity, the mounting base 36 of the core section 38 is shown transparent. In the area of the mounting base 36, recesses 34 are formed in the core section 38, which connect the recesses 34 on the peripheral wall 39 of the core section 38 to one another. Moreover, recesses 34 are formed in the region of the mounting base 36 of the bell section 44 and connect loop-shaped recesses 34 on the peripheral wall 39 of the core section 38. This forms pulsating heat pipes 30 in the mounting base 36, which in turn utilize the surface area of the mounting base 36 of the core section 38 for heat dissipation 19. There is also a computer program product 60, which is not shown in detail, which is configured as a “digital twin” of the supporting apparatus 10. The computer program product 60 can comprise an image, in particular a digital image, of the supporting apparatus 10 and can be configured to simulate a prevailing operating state of the supporting apparatus 10.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements that perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-15. (canceled)

16. A supporting apparatus for mechanically supporting an electrically conductive connecting element, which is to be cooled, on a heat sink, which electrically insulates the connecting element from the heat sink, the supporting apparatus comprising:
at least one pulsating heat pipe is formed in the supporting apparatus for dissipating heat from the connecting element into the heat sink;
wherein the at least one pulsating heat pipe is at least partially provided with a diffusion-inhibiting coating.

17. The supporting apparatus as claimed in claim 16, wherein the supporting apparatus is formed in a middle section from a first material with a first thermal conductivity and is produced at at least one of (i) a connecting element-side end and (ii) a heat sink-side end from a second material with a second thermal conductivity.

18. The supporting apparatus as claimed in claim 16, further comprising:
a mounting base formed at the connecting element-side end; and
at least one pulsating heat pipe extending through the mounting base.

19. The supporting apparatus as claimed in claim 17, further comprising:
a mounting base formed at the connecting element-side end; and
wherein the at least one pulsating heat pipe extends through the mounting base.

20. The supporting apparatus as claimed in claim 16, wherein the at least one pulsating heat pipe is filled at least partially with an electrically conductive fluid.

21. The supporting apparatus as claimed in claim 16, wherein the supporting apparatus is formed in one piece or has a core section, on which a bell section is attached.

22. The supporting apparatus as claimed in claim 16, wherein a plurality of pulsating heat pipes is formed in the region of a circumferential wall between the connecting element-side end and the heat sink-side end.

23. The supporting apparatus as claimed in claim 16, wherein the diffusion-inhibiting coating is produceable by one of gas phase deposition, physical vapor deposition, a sol-gel process, thermal spraying, vapor deposition, autocatalytic coating and an electroplating process.

24. The supporting apparatus as claimed in claim 22, wherein at least one of the circumferential wall, the connecting element-side end and the heat sink-side end of the supporting apparatus are provided with a diffusion-inhibiting coating on their surface or inside thereof.

25. The supporting apparatus as claimed in claim 23, wherein at least one of the circumferential wall, the connecting element-side end and the heat sink-side end of the supporting apparatus are provided with a diffusion-inhibiting coating on their surface or inside thereof.

26. The supporting apparatus as claimed in claim 16, wherein the at least one pulsating heat pipe is closed by at least one of the heat sink and the connecting element.

27. The supporting apparatus as claimed in claim 16, further comprising:
a sensor for detecting at least one of a physical variable of the at least one pulsating heat pipe and a component of the supporting apparatus.

28. The supporting apparatus as claimed in claim 16, wherein the supporting apparatus has on the connecting element-side end and/or on the heat sink-side end a recess via which an indented surface provides a heat coupling to the connecting element, which is to be cooled, or the heat sink.

29. The supporting apparatus as claimed in claim 28, wherein a coupling element made of a metal material is accommodated in the recess which forms the indented surface for heat coupling.

30. The supporting apparatus as claimed in claim 16, wherein the supporting apparatus is produced at least in part by an additive manufacturing process.

31. A power module comprising a substrate with at least one electrically conductive connecting element which is to be cooled; wherein the connecting element is mounted on a heat sink supported by the supporting apparatus; an wherein the supporting apparatus is configured as claimed in claim 16.

32. A computer program comprising commands stored memory which, when executed by a processor of a computer, cause the computer to simulate an operational behavior of a supporting apparatus as claimed in claim 16.
